(19) United States
(12) Patent Application Publication
(10) Pub. No.: US 2013/0214419 A1
(43) Pub. Date: Aug. 22, 2013

(54) SEMICONDUCTOR PACKAGING METHOD AND STRUCTURE THEREOF

(71) Applicants: Cheng-Hung Shih, Changhua County (TW); Shu-Chen Lin, Pingtung County (TW); Cheng-Fan Lin, Hsinchu County (TW); Yung-Wei Hsieh, Hsinchu City (TW); Ming-Yi Liu, Hsinchu County (TW)

(72) Inventors: Cheng-Hung Shih, Changhua County (TW); Shu-Chen Lin, Pingtung County (TW); Cheng-Fan Lin, Hsinchu County (TW); Yung-Wei Hsieh, Hsinchu City (TW); Ming-Yi Liu, Hsinchu County (TW)

(73) Assignee: CHIPBOND TECHNOLOGY CORPORATION, Hsinchu (TW)

(21) Appl. No.: 13/398,059

(22) Filed: Feb. 16, 2012

(51) Int. Cl. H01L 23/48; H01L 21/56; H01L 21/60

(52) U.S. Cl. 257/773; 438/126; 257/E23.01; 257/E21.506; 257/E21.503

(57) ABSTRACT

A semiconductor packaging method includes providing a substrate having a plurality of connection pads; mounting a chip on the substrate, wherein the chip comprises a plurality of copper-containing bumps directly coupled to the connection pads, and each of the copper-containing bumps comprises a ring surface; forming an anti-dissociation gel between the substrate and the chip, wherein the anti-dissociation gel comprises a plurality of anti-dissociation substances, and the ring surfaces of the copper-containing bumps are covered by the anti-dissociation substances.

### FIELD OF THE INVENTION

The present invention is generally related to a semiconductor packaging method, which particularly relates to the semiconductor packaging method that prevents copper ions from dissociation.

### BACKGROUND OF THE INVENTION

Modern electronic products gradually lead a direction of light, thin, short, and small. Accordingly, the circuit layout for electronic products destines to develop technique such as “micro space between two electronic connection devices”. However, a short phenomenon is easily occurred in mentioned circuit layout via an insufficient gap between two adjacent electronic connection devices.

### SUMMARY

The primary object of the present invention is to provide a semiconductor packaging method includes providing a substrate having a top surface and a plurality of connection pads disposed at the top surface, and each of the connection pads comprises a first linking surface; mounting a chip on the substrate, the chip comprises an active surface and a plurality of copper-containing bumps disposed at the active surface, wherein the active surface faces toward the top surface of the substrate, each of the copper-containing bumps is directly coupled to each of the connection pads and comprises a second linking surface and a ring surface; forming an anti-dissociation gel between the substrate and the chip, wherein the anti-dissociation gel comprises a plurality of anti-dissociation substances, and the ring walls of the copper-containing bumps are covered with the anti-dissociation substances. As a result of the copper-containing bumps being covered by the anti-dissociation substances of the anti-dissociation gel, when a dissociation phenomenon from copper ions is occurred, the anti-dissociation substances may capture those dissociated copper ions to avoid short phenomenon from happening.

### DESCRIPTION OF THE DRAWINGS

FIGS. 1A to 1C are section schematic diagrams illustrating a semiconductor packaging method in accordance with a preferred embodiment of the present invention.

### DETAILED DESCRIPTION OF THE INVENTION

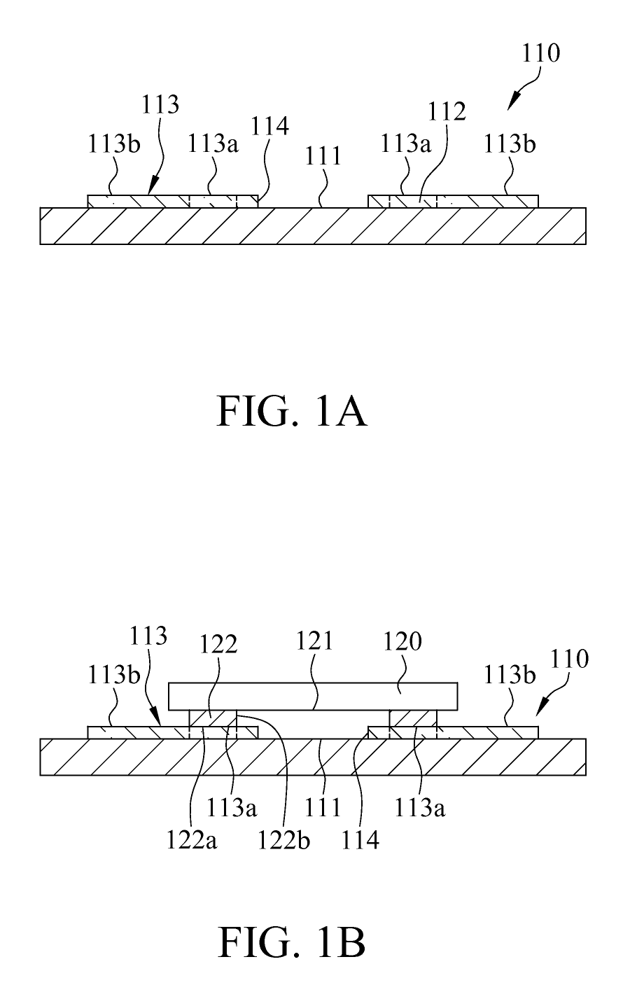

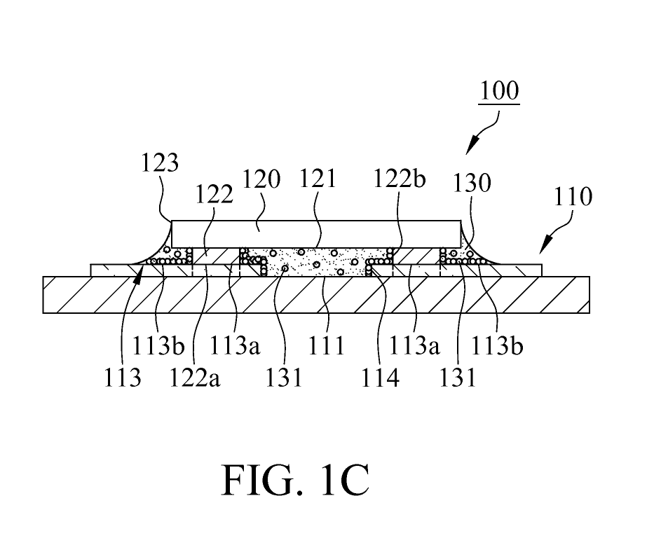

With reference to FIGS. 1A to 1C, a semiconductor packaging method in accordance with a preferred embodiment of the present invention includes the steps as followed. First, referring to FIG. 1A, providing a substrate 110 having a top surface 111 and a plurality of connection pads 112 disposed at the top surface 111, wherein each of the connection pads 112 comprises a first linking surface 113 and a lateral face 114. In this embodiment, the first linking surface 113 of each of the connection pads 112 comprises a first area 113a and a second area 113b located outside the first area 113a. Next, referring to FIG. 1B, mounting a chip 120 on the substrate 110, the chip 120 comprises an active surface 121 and a plurality of copper-containing bumps 122 disposed at the active surface 121, wherein the active surface 121 faces toward the top surface 111 of the substrate 110, each of the copper-containing bumps 122 is directly coupled to each of the connection pads 112 and comprises a second linking surface 122a and a ring surface 122b. In this embodiment, the material of the copper-containing bumps 122 can be chosen from one of copper/nickel or copper/nickel/gold. Besides, each of the first areas 113a is corresponded to the second linking surface 122a of each of the copper-containing bumps 122. In addition, each of the first linking surfaces 113 and each of the second linking surfaces 122a are coplanar. Eventually, referring to FIG. 1C, forming an anti-dissociation gel 130 between the substrate 110 and the chip 120. In this embodiment, the anti-dissociation gel 130 is extendedly formed at a lateral surface 123 of the chip 120 and comprises a plurality of anti-dissociation substances 131. The ring surfaces 122b of the copper-containing bumps 122 and the lateral faces 114 of the connection pads 112 are covered with the anti-dissociation substances 131. Preferably, the anti-dissociation substances 131 further cover the second areas 113b of the first linking surfaces 113 therefore forming a semiconductor packaging structure 100. In this embodiment, the anti-dissociation substance 131 can be an organic solderability preservative, and the material of the organic solderability preservative can be chosen from one of benzimidazole or imidazole derivative. The imidazole derivative can be one of Brenzotriazole, Phenylimidazole, Substituted Benzimidazole, Aryl Phonylimidazole or a mixture thereof, and the benzimidazole can be one of Brenzotriazole, Phenylimidazole, Substituted Benzimidazole, Aryl Phonylimidazole or a mixture thereof. As a result of the copper-containing bumps 122 being covered by the anti-dissociation substances 131 of the anti-dissociation gel 130, when a dissociation phenomenon via copper ions within the copper-containing bumps 122 is occurred, the anti-dissociation substances 131 may capture those dissociated copper ions in time to avoid short phenomenon from happening.

With reference to FIG. 1C again, a semiconductor packaging structure 100 in accordance with a preferred embodiment of this invention includes a substrate 110, a chip 120 and an anti-dissociation gel 130. The substrate 110 comprises a top surface 111 and a plurality of connection pads 112 disposed at the top surface 111, wherein each of the connection pads 112 comprises a first linking surface 113 and a lateral face 114. The first linking surface 113 of each of the connection pads 112 comprises a first area 113a and a second area 113b located outside the first area 113a. The chip 120 is mounted on the substrate 110 by using flip-chip mounting, the chip 120 comprises an active surface 121 and a plurality of copper-containing bumps 122 disposed at the active surface 121, wherein the active surface 121 faces toward the top surface 111 of the substrate 110, each of the copper-containing bumps 122 is directly coupled to each of the connection pads 112 and comprises a second linking surface 122a and a ring surface 122b. Besides, each of the first areas 113a is corresponded to the second linking surface 122a of each of the copper-containing bumps 122. In addition, each of the first linking surfaces 113 and each of the second linking surfaces 122a are coplanar. The anti-dissociation gel 130 is formed between the substrate 110 and the chip 120, wherein the anti-dissociation gel 130 is extendedly formed at a lateral surface 123 of the chip 120 and comprises a plurality of anti-dissociation substances 131. The ring surfaces 122b of the copper-containing bumps 122 and the lateral faces 114 of the connection pads 112 are covered with the anti-dissociation substances 131. Furthermore, the second areas 113b of the first linking surfaces 113 of the connection pads 112 are covered with the anti-dissociation material 131.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

1. A semiconductor packaging method at least comprising:
providing a substrate having a top surface and a plurality of connection pads disposed on the top surface, wherein each of the connection pads comprises a first linking surface;
mounting a chip on the substrate, wherein the chip comprises an active surface facing toward the top surface of the substrate and a plurality of copper-containing bumps disposed at the active surface, the copper-containing bumps are directly coupled to the connection pads, and each of the copper-containing bumps comprises a second linking surface and a ring surface; and
forming an anti-dissociation gel between the substrate and the chip, wherein the anti-dissociation gel comprises a plurality of anti-dissociation substances, and wherein said anti-dissociation substances cover the ring surfaces of the copper-containing bumps and capture dissociated copper ions from the copper-containing bumps to inhibit short phenomena.

2. The semiconductor packaging method in accordance with claim 1, wherein each of the first linking surfaces and each of the second linking surfaces are coplanar.

3. The semiconductor packaging method in accordance with claim 1, wherein each of the connection pads comprises a lateral face being covered with the anti-dissociation substances.

4. The semiconductor packaging method in accordance with claim 1, wherein the first linking surface of each of the connection pads comprises a first area and a second area located outside the first area, and each of the first areas is corresponded to the second linking surface of each of the copper-containing bumps.

5. The semiconductor packaging method in accordance with claim 4, wherein the second areas of the first linking surfaces are covered with the anti-dissociation substances.

6. The semiconductor packaging method in accordance with claim 1, wherein the anti-dissociation substances comprise organic solderability preservatives.

7. The semiconductor packaging method in accordance with claim 6, wherein the material of the organic solderability preservatives is chosen from one of benzimidazole or imidazole derivative.

8. The semiconductor packaging method in accordance with claim 7, wherein the imidazole derivative is one of Brenzotriazole, Phenylimidazole, Substituted Benzimidazole, Aryl Phonylimidazole or a mixture thereof, and the benzimidazole is one of Brenzotriazole, Phenylimidazole, Substituted Benzimidazole, Aryl Phonylimidazole or a mixture thereof.

9. The semiconductor packaging method in accordance with claim 1, wherein the material of the copper-containing bumps is one of copper/nickel or copper/nickel/gold.

10. A semiconductor packaging structure at least includes:
a substrate having a top surface and a plurality of connection pads disposed at the top surface, each of the connection pads comprises a first linking surface;
a chip mounted on the substrate, the chip comprises an active surface and a plurality of copper-containing bumps disposed at the active surface, wherein the active surface faces toward the top surface of the substrate, each of the copper-containing bumps is directly coupled to each of the connection pads and comprises a second linking surface and a ring surface; and
an anti-dissociation gel formed between the substrate and the chip, the anti-dissociation gel comprises a plurality of anti-dissociation substances, wherein the ring surfaces of the copper-containing bumps are covered with the anti-dissociation substances and wherein the anti-dissociation substances capture dissociated copper ions from the copper-containing bumps to inhibit short phenomena.

11. The semiconductor packaging structure in accordance with claim 10, wherein each of the first linking surfaces and each of the second linking surfaces are coplanar.

12. The semiconductor packaging structure in accordance with claim 10, wherein each of the connection pads comprises a lateral face being covered with the anti-dissociation substances.

13. The semiconductor packaging structure in accordance with claim 10, wherein the first linking surface of each of the connection pads comprises a first area and a second area located outside the first area, and each of the first areas is corresponded to the second linking surface of each of the copper-containing bumps.

14. The semiconductor packaging structure in accordance with claim 13, wherein the second areas of the first linking surfaces are covered with the anti-dissociation substances.

15. The semiconductor packaging structure in accordance with claim 10, wherein the anti-dissociation substances comprise organic solderability preservatives.

16. The semiconductor packaging structure in accordance with claim 15, wherein the material of the organic solderability preservatives is chosen from one of benzimidazole or imidazole derivative.

17. The semiconductor packaging structure in accordance with claim 16, wherein the imidazole derivative is one of Brenzotriazole, Phenylimidazole, Substituted Benzimidazole, Aryl Phonylimidazole or a mixture thereof, and the benzimidazole is one of Brenzotriazole, Phenylimidazole, Substituted Benzimidazole, Aryl Phonylimidazole or a mixture thereof.

18. The semiconductor packaging structure in accordance with claim 10, wherein the material of the copper-containing bumps is one of copper/nickel or copper/nickel/gold.
